(19) United States
(12) Patent Application Publication
(10) Pub. No.: US 2025/0344470 A1
(43) Pub. Date: Nov. 6, 2025

(54) SEMICONDUCTOR DEVICE WITH HIGH-VOLTAGE SEMICONDUCTOR ELEMENT

(71) Applicant: Infineon Technologies Austria AG, Villach (AT)

(72) Inventors: Franz Hirler, Isen (DE); Lars Müller-Meskamp, Dresden (DE); Tom Peterhãnsel, Dresden (DE); Fabian Geisenhof, München (DE)

(21) Appl. No.: 19/191,536

(22) Filed: Apr. 28, 2025

(30) Foreign Application Priority Data
May 2, 2024 (DE) 102024204102.5

(51) Int. Cl. H10D 62/10; H03K 17/687; H10D 8/00; H10D 30/65; H10D 62/60

(52) U.S. Cl. CPC H10D 62/126; H03K 17/6871; H10D 8/411; H10D 30/657; H10D 62/109; H10D 62/60

(57) ABSTRACT

A semiconductor device includes a high-voltage semiconductor element with a first doped region of a first conductivity type. The first doped region at least partly laterally surrounds a central portion. The central portion and the first doped region may form an auxiliary junction. A second doped region of a second conductivity type at least partly laterally surrounds the first doped region. A drift region of the first or second conductivity type extends from the first doped region to the second doped region, and forms a first pn junction with the first doped region or the second doped region.

### TECHNICAL FIELD

The present disclosure relates to a semiconductor device having a high-voltage semiconductor element with a drift zone. Examples of the present disclosure relate to gate driver circuits with active high-voltage semiconductor elements electrically connected between a high voltage part and a low voltage part.

### BACKGROUND

HV (high-voltage) semiconductor devices in CMOS technology (complementary metal oxide semiconductors) form an interface between standard CMOS devices with input voltages up to 5V on the one hand and industrial or consumer circuits operating with signal voltage levels above 30V on the other. Applications for such HV semiconductor devices exist in all kinds of power conversion and electrical drives up to the kW range, e.g., in power converters, robotics and the automotive industry. Such HV semiconductor devices typically include a low voltage part operating in a low voltage domain and a high voltage part operating in a high voltage domain. In the low voltage part, most of the signal processing is done at low operating voltage. The high voltage part operates at higher voltage level. The low voltage part and the high voltage part provide signal interfaces for power semiconductors using higher voltage levels and/or having higher current driving and sinking capability. The electric potentials of the different voltage domains can differ by several 100V up to some 1000V. An example of such a HV semiconductor device is a gate driver circuit. Gate driver circuits allow a microcontroller or DSP (digital signal processor) to efficiently turn on and off power semiconductor switches. Such HV semiconductor devices include high-voltage semiconductor elements for exchanging electric power and/or electric signals between the CMOS circuits in the different voltage domains.

There is a constant need to improve signal transmission in semiconductor devices with high-voltage semiconductor elements with little additional effort.

### SUMMARY

High-voltage semiconductor elements include a lightly doped drain extension (drift zone) to separate two element regions operating in different voltage domains. In the blocking state of the high-voltage semiconductor element, the low doping of the drift zone keeps the electric field between the two element regions moderate. The drift zone may have the shape of a circular ring that separates a circular or stadium shaped first element region, which is assigned to a first voltage domain, from a ring-shape second element region, which is assigned to another voltage domain. The radius of an inner curvature of the drift zone must be sufficiently large to prevent premature breakdown below a nominal breakdown voltage. The area of the first element region laterally at least partially surrounded by the drift zone increases with the radius of the inner curvature of the drift zone. As the area of the first element region increases, its effective capacitance increases. The effective capacitance limits the transmission frequency for a signal transmitted through the high-voltage semiconductor element.

A semiconductor device in accordance with the pertinent disclosure includes a high-voltage semiconductor element. The high-voltage semiconductor element includes a first doped region of a first conductivity type at least partially laterally surrounding a central portion, wherein the central portion and the first doped region form an auxiliary junction. A second doped region of a second conductivity type at least partially laterally surrounds the first doped region. A drift region of the first or second conductivity type extends from the first doped region to the second doped region. The drift region forms a first pn junction with the first doped region or the second doped region.

The area which is at least partly surrounded by the lightly doped drift zone is divided into the first doped region and the central portion. Only the first doped region assumes the function of an active element region of the high-voltage semiconductor element. The central portion can be designed in such a way that it does not to significantly contribute to the effective capacitance of the first doped region but still leads only to a very minor reduction in breakdown voltage. The effective capacitance of the first doped region is reduced. The transmission speed can be increased.

The invention relates to semiconductor devices having a high voltage domain and a low voltage domain. One specific example for such a high voltage semiconductor device is a gate driver device having a high side part operating in a high voltage domain and a low side part operating in a low voltage domain.

Those skilled in the art will recognize additional features and advantages by reading the following detailed description and viewing the accompanying drawings.

### BRIEF DESCRIPTION OF THE DRAWINGS

The accompanying drawings are provided for further understanding of the embodiments and form an integral part of this description. The drawings illustrate embodiments of a semiconductor device with a high-voltage semiconductor element and, together with the description, explain the principles underlying the embodiments. Further embodiments are described in the following detailed description and in the claims. Features of the various embodiments may be combined with each other.

FIGS. 1A and 1B include a schematic plan view and a schematic vertical cross-sectional view of a portion of a semiconductor device in accordance with an embodiment with a semiconductor diode as high-voltage semiconductor element.

FIGS. 2A and 2B include a schematic plan view and a schematic vertical cross-sectional view of a portion of a semiconductor device in accordance with an embodiment with a lateral n-channel LDMOS field effect transistor with central drain as high-voltage semiconductor element.

FIGS. 3A and 3B include a schematic plan view and a schematic vertical cross-sectional view of a portion of a semiconductor device in accordance with an embodiment with a lateral p-channel LDMOS field effect transistor with central source.

FIG. 3C includes a further schematic vertical cross-sectional view of a portion of a semiconductor device in accordance with an embodiment with a lateral p-channel LDMOS field effect transistor with central source and RESURF layer.

FIG. 4A illustrates a schematic plan view of a semiconductor device with a high side part, a low side part and two high-voltage semiconductor elements according to an embodiment.

FIG. 4B illustrates a schematic plan view of a semiconductor device with a high-voltage semiconductor element having two straight, parallel long sides and two semicircular portions terminating the two long sides on opposite sides according to an embodiment.

FIG. 5 and FIG. 6 illustrate schematic vertical cross-sectional views of portions of semiconductor devices with a high-voltage semiconductor element with homogenous central portion in accordance with embodiments.

FIG. 7 and FIG. 8 illustrate schematic vertical cross-sectional views of portions of semiconductor devices with a high-voltage semiconductor element with a central portion including a doped ring portion and floating island region in accordance with embodiments.

FIG. 9 and FIG. 10 illustrate schematic vertical cross-sectional views of portions of semiconductor devices with a high-voltage semiconductor element with a central portion including an oppositely doped separation portion between a doped ring portion and a floating island region in accordance with embodiments.

FIG. 11 illustrates a schematic vertical cross-sectional view of a portion of semiconductor devices with a high-voltage semiconductor element in accordance with an embodiment related to a silicon-on-insulator concept.

FIG. 12A and FIG. 12B schematically illustrate equipotential lines in vertical cross-sectional views of a high-voltage semiconductor element according to a comparative example and a high-voltage semiconductor element according to an embodiment for discussing effects of the embodiments.

FIG. 13A and FIG. 13B schematically illustrate displacement current distributions in vertical cross-sectional views of a high-voltage semiconductor element according to a comparative example and a high-voltage semiconductor element according to an embodiment for discussing effects of the embodiments.

FIG. 14 is a diagram showing the output capacitance as a function of the drain-to-source voltage VDS for different embodiments and a comparative example for discussing effects of the embodiments.

FIG. 15 is a diagram showing the breakdown voltage of an LDMOS field effect transistor as a function of a distance between a doped ring portion and a floating island region for discussing effects of the embodiments.

FIG. 16 is a diagram showing the output capacitance of an LDMOS field effect transistor as a function of a distance between a doped ring portion and a floating island region for discussing effects of the embodiments.

FIG. 17 is a schematic block diagram of a gate driver circuit with LDMOS field effect transistors for passing a differential data signal from a high side part to a low side part in accordance with an embodiment.

### DETAILED DESCRIPTION

In the following detailed description, reference is made to the accompanying drawings which form a part of this document and in which certain embodiments of a semiconductor device with a high-voltage semiconductor element are shown as illustrations. Structural or logical changes may be made to the illustrated embodiments without departing from the scope of the present disclosure. For example, features shown or described for one embodiment may be used on or in conjunction with other embodiments, resulting in another embodiment. The present disclosure is intended to include such modifications and variations. The embodiments are described in a manner that should not be construed as limiting the scope of the appended claims. The drawings are not to scale and are for illustrative purposes only. Corresponding elements are designated by the same reference numerals in the various drawings, unless otherwise indicated.

The terms “having”, “containing”, “including”, “comprising” and the like are open-ended, and the terms indicate the presence of certain structures, elements or features but do not preclude the presence of additional elements or features. The articles “a”, “an” and “the” include both the plural and singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

The term “directly electrically connected” describes a permanent low-resistive ohmic connection between electrically connected elements, for example a direct contact between the concerned elements or a low-resistive connection via a metal and/or heavily doped semiconductor material.

The terms “signal-connected” and “electrically coupled” include a permanent low-resistive ohmic connection between electrically connected elements, for example a direct contact between the concerned elements or a low-resistive connection via a metal and/or heavily doped semiconductor material, but do not preclude the presence of further passive and/or active elements in the signal path between the “signal-connected” or “electrically coupled” elements. For example, the further elements may include resistors, resistive conductor lines, capacitors and/or inductors, transistors, semiconductor diodes, Schottky diodes, transformers, opto-couplers and other.

The term “power semiconductor device” refers to semiconductor devices with a high voltage blocking capability of at least 30 V, for example 48 V, 100 V, 600 V, 1.6 kV, 3.3 kV or more and with a nominal on-state current or forward current of at least 200 mA, for example 1 A, 10 A or more.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

Ranges given for physical dimensions include the boundary values. For example, a range for a parameter y from a to b reads as a≤y≤b. The same holds for ranges with one boundary value like “at most” and “at least”.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

Two adjoining doping regions in a semiconductor layer form a semiconductor junction. Two adjoining doping regions of the same conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa. Two adjoining doping regions of complementary conductivity form a pn junction.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The present disclosure concerns a semiconductor device including a high-voltage semiconductor element. The high-voltage semiconductor element includes a first doped region of a first conductivity type. The first doped region at least partially laterally surrounds a central portion. The central portion and the first doped region form an auxiliary junction. A second doped region of a second conductivity type at least partially laterally surrounds the first doped region. A drift region of the first or second conductivity type extends from the first doped region to the second doped region. The drift region forms a first pn junction with the first doped region or the second doped region.

The high-voltage semiconductor element may be a power semiconductor diode with high breakdown voltage or a power LDMOS field effect transistor high with breakdown voltages. Semiconducting element regions of the high-voltage semiconductor element are formed in a semiconductor layer. The semiconductor layer has a planar first substrate surface that extends in horizontal directions. A normal on the first substrate surface defines a vertical direction.

The central portion may be circular, rectangular with rounded corners, or stadium-shaped including a rectangle and two semicircles on opposite sides of the rectangle, wherein a diameter of the semicircles and a side length of the rectangle oriented to one of the semicircles are equal.

The first doped region may be a multipart structure with sub-portions on opposite sides of the central portion. For example, the first doped region may include two parallel, straight sub-portions of different or the same length on opposite long sides of a stadium-shaped central portion.

Alternatively, the first doped region may be a one-part structure forming a closed ring around the central portion. The first doped region may form a point-symmetric circular ring or a basically rectangular frame with rounded corners or a basically rectangular frame with two semicircular portions on opposite sides (stadium). The ring or frame can be fully closed or may have one or more gaps. The first doped region is in direct lateral contact with the central portion.

The first doped region and the central portion form an auxiliary junction. The auxiliary junction may be a semiconductor/insulator junction or a semiconductor junction.

The second doped region is formed at a uniform distance to the first doped region. The second doped region may include one or two straight sections in uniform distance to one or two straight sections of the first doped region. The second doped region may be a one-piece structure forming a closed ring around the first doped region, wherein the second doped region is formed at a lateral distance from the first doped region. The lateral distance between the first doped region and the second doped region may be the same along the entire circumference of the first doped region. The second doped region may form a point-symmetric circular ring or a basically rectangular frame with rounded corners or a basically rectangular frame with two semicircular portions on opposite sides. The ring or frame may be fully closed or may have one, two or more gaps.

The drift region may laterally separate the first doped region and the second doped region. When the drift region has the first conductivity type, the drift region and the first doped region may form a unipolar junction, and the drift region and the second doped region may form the first pn junction.

When the drift region has the second conductivity type, the drift region and the first doped region may form the first pn junction, and the drift region and the second doped region may form a unipolar junction.

The central portion may be a homogenous part of the semiconductor layer with uniform dopant concentration. Alternatively, the dopant concentration in the central portion may change gradually and/or stepwise along the radial direction and/or the vertical direction. When the central portion has the same conductivity type as the first doped region, an average dopant concentration in the central portion is at most 1% of the average dopant concentration in the first doped region. A maximum dopant dose in a homogenous central portion without steep changes in dopant concentration changes can be 1e16 cm⁻², e.g. 1e15 cm⁻² or 1e14 cm⁻².

The central portion may form a circle, a rectangle with rounded corners, or a combination of a rectangle with two symmetric semicircular portions on two opposite sides of the rectangle.

The necessary radius of an outer curvature of the first doped region increases with the desired nominal breakdown voltage of the high-voltage semiconductor element. With increasing radius of the outer curvature, the area and the effective capacitance of the first doped region increases. The curvature radius may be at least 5 μm, 15 μm or even 25 μm. The central portion reduces the effective area of the first doped region and, consequently, the effective capacitance of the first doped region. A transmission of frequency the high-voltage semiconductor element can be increased.

According to an embodiment, the auxiliary junction may include a unipolar junction or a pn junction. For example, the auxiliary junction is a unipolar junction or a pn junction, wherein a pn junction may become effective at a lower voltage than a unipolar junction.

According to an embodiment, the drift region may include or consist of a doped drift zone of the first or second conductivity type extending between the first surface of the semiconductor layer and a lightly doped base portion of the semiconductor layer from the first doped region to the second doped region, wherein the doped drift zone forms the first pn junction with the first doped region or the second doped region.

The doped drift zone may laterally separate the first doped region and the second doped region. When the doped drift zone has the first conductivity type, the doped drift zone and the first doped region form a unipolar junction, and the doped drift zone and the second doped region form the first pn junction.

When the doped drift zone has the second conductivity type, the doped drift zone and the first doped region form the first pn junction, and the doped drift zone and the second doped region form a unipolar junction.

According to an embodiment, the semiconductor element may include a semiconductor diode with a first one of the first doped region and the second doped region forming a diode anode region and with a second one of the first doped region and the second doped region forming a diode cathode region.

If the first conductivity type is the n-type, the first doped region is n doped and forms the diode cathode region. The second doped region is p doped and forms the diode anode region. The drift region can be lightly n doped, wherein the first pn junction is formed between the drift region and the second doped region. Alternatively, the drift region is lightly p doped, wherein the first pn junction is formed between the first doped region and the drift region.

The semiconductor diode may be configured as bootstrap diode that periodically charges a bootstrap capacitor in the high voltage part from a supply voltage for the low voltage part. Reducing the active cathode area by providing the inactive central portion reduces current injection. A reduced forward current may improve device ruggedness.

According to another embodiment, the semiconductor device may further include a third doped region of the conductivity type of the first doped region. The third doped region is laterally separated from the drift region by a transistor body region of a complementary conductivity type, wherein the transistor body region includes at least a portion of the second doped region or the first doped region.

The third doped region is part of the high-voltage semiconductor element and complements the first and second doped regions to form a lateral field effect transistor, wherein the first doped region may form a transistor drain region or a transistor body region embedding a transistor source region.

A doped drift zone may form a drain extension and the semiconductor element may be configured as level shifter LDMOS (laterally-diffused metal-oxide semiconductor) field effect transistor for transmitting electric signals between a low side part and a high side part of the semiconductor device.

According to an embodiment of a semiconductor device with a third doped region, the third doped region may be embedded in the second doped region, wherein the second doped region and the third doped region form a second pn junction.

If the first conductivity type is n-type, the first doped region forms an n conductive transistor drain region. The drift region is n conductive. An n conductive drift zone may at least partially laterally surround the transistor drain region. The drift region laterally separates the transistor drain region and the transistor body region. The second doped region forms a p conductive transistor body region at least partially laterally surrounding the drift region. The second doped region laterally and vertically embeds the third doped region in the semiconductor layer in three directions. The third doped region forms an n conductive transistor source region extending from the first surface of the semiconductor layer into the first doped region. The first pn junction is formed between the drift region and the transistor body region (second doped region). The second pn junction is formed between the transistor body region (second doped region) and the transistor source region (third doped region).

The high-voltage semiconductor element forms a “drain-inside” n channel enhancement-type LDMOS field effect transistor that may be configured to transmit an electric signal from a low side part to a high side part of the semiconductor device.

According to another embodiment of a semiconductor device with a third doped region, the first doped region may laterally embed the third doped region, wherein the first doped region and the third doped region form a second pn junction.

If the first conductivity type is n-type, the first doped region forms an n conductive transistor body region. The drift region is p conductive and laterally surrounds the n conductive transistor body region. A doped drift zone is p conductive and partly or completely laterally surrounds the n conductive transistor body region. The second doped region forms a p conductive transistor drain region partly or completely laterally surrounding the doped drift zone. The third doped region forms a p conductive transistor source region extending from the first surface of the semiconductor layer into the first doped region. The first doped region embeds the p conductive transistor source region at all lateral sides and along the vertical direction. The first pn junction is formed between the transistor body region (first doped region) and the drift region. The second pn junction is formed between the transistor body region (first doped region) and the transistor source region (third doped region).

The high-voltage semiconductor element forms a “source-inside” p channel enhancement-type LDMOS field effect transistor that transmits electric signals from a high side part to a low side part of the semiconductor device.

According to an embodiment, at least three of the first doped region, the drift region, the second doped region and the third doped region may form wells extending from a first surface of a semiconductor layer into the semiconductor layer.

The semiconductor layer may include a single-crystalline silicon layer of uniform vertical extension (thickness) between two parallel main surfaces of the semiconductor layer. The main surface at a front side forms a first surface. The opposite main surface is referred to as second surface or back side in the following. Structures including other materials, e.g., non-semiconducting materials may extend from one of the main surfaces or both main surfaces into the semiconductor layer. A vertical extension of the semiconductor layer may be in a range from 10 μm to 200 μm, e.g., in a range from 35 μm to 80 μm.

The semiconductor layer may have a homogeneous background doping. For example, the semiconductor layer may be lightly p doped or lightly n doped. A drift portion of the semiconductor layer having the background doping may form the drift region. The other doped regions may be formed by implanting dopants through the first surface and activating the implanted dopants in a heat treatment. A remaining portion of the semiconductor layer spared from and not affected by the implanted dopants forms a base portion having the original background doping of the semiconductor layer. The base portion may include one, two or more drift portions.

According to an embodiment the doped drift zone may be configured to be fully depleted at a voltage lower than 30% of a breakdown voltage of the semiconductor device.

The breakdown voltage may by a curvature limited breakdown voltage through the drift region. For example, a doped drift zone may be fully depleted at a voltage lower than 50% of the breakdown voltage of the semiconductor device, or at least at the breakdown voltage.

The doped drift zone is sufficiently thin and sufficiently weakly doped such that with increasing blocking voltage a space charge region formed along the horizontal pn junction between the doped drift zone and the base portion extends up to the first surface of the semiconductor layer before a lateral breakdown occurs across the doped drift zone. The doped drift zone may embody a RESURF (reduced surface field) concept for an LDMOS field effect transistor or a lateral semiconductor diode.

The RESURF concept may further include a RESURF layer having a conductivity type complementary to the conductivity type of the doped drift zone and being in direct contact with the doped drift zone. The RESURF layer may be formed between the first surface of the semiconductor layer and the doped drift zone and/or between the doped drift zone and the base portion. The RESURF layer may extend along the complete radial extension of the doped drift zone or along a portion of the lateral extension in the radial direction, e.g., along at least 20%, at least 50% or at least 80% of the radial extension of the doped drift zone.

According to an embodiment, the semiconductor device may include an insulator layer formed along a second surface of the semiconductor layer. The second surface is opposite to the first surface.

The semiconductor layer and the insulator layer are in direct contact with each other and form a horizontal interface. A vertical extension of the insulator layer may be in a range from 2 μm to 40 μm, e.g., in a range from 4 μm to 20 μm. The semiconductor layer and the insulator layer may form an SOI (silicon-on-insulator) die. The insulation layer may include or consist of different material layers.

According to an embodiment, the semiconductor device may include an insulator structure extending from the first surface of the semiconductor layer to the insulator layer, wherein the insulator structure laterally surrounds an element portion of the semiconductor layer, the element portion including doped regions of the semiconductor element.

The insulator structure may laterally surround a portion of the semiconductor layer that includes all doped regions of the semiconductor element, in particular, the central portion, the diode anode region, the drift region and the diode cathode region of a semiconductor diode. Alternatively, the insulator structure may laterally surround a portion of the semiconductor layer that includes the central portion, the transistor drain region, the drift region, the transistor body region and the transistor source region of an LDMOS field effect transistor.

The insulator structure may extend down to or into the insulator layer. The insulator structure may include exclusively one or more dielectric materials, or may include a conductive fill and an insulating lining layer, that separates the conductive fill from the material of the semiconductor layer.

The insulator structure may comprise at least one insulator trench electrically insulating the semiconductor element from a further semiconductor element neighboring the semiconductor element on the same semiconductor substrate. The insulator trench may comprise a trench insulator layer. The insulator trench may comprise a trench electrode. Said trench electrode may comprise with doped or undoped polysilicon. Said trench electrode may be floating or be connected to any potential. The trench electrode may be insulated from the semiconductor layer by the trench insulator layer of the insulator trench. The at least one insulator trench may extend from the front side of the semiconductor layer to the back side of the semiconductor layer. At the back side of the semiconductor layer, the at least one insulator trench may adjoin the insulator layer.

The semiconductor device may further comprise an additional silicon layer below the back side of the semiconductor substrate. For example, the additional silicon layer may be attached directly or indirectly to the insulator layer. For example, one or more adhesion promotion layers may be arranged in-between the insulator layer and the additional silicon layer. The one or more adhesion promotion layer may include a tape, e.g. a DAF tape. For example, alternatively or additionally to the one or more adhesion promotion layers one or more further layer may be arranged in-between the insulator layer and the additional silicon layer. The one or more further layer may include one or more dielectric and/or one or more metal layer.

According to an embodiment, the central portion may have the second conductivity type or may have the first conductivity type with a maximum dopant concentration of at most 10% of an average dopant concentration in the first doped region.

If the central portion and the first doped region have the same conductivity type and are electrically connected, the central portion is charged together with the first doped region. The capacitance contribution of the central portion decreases as the dopant concentration decreases because the space charge region widens.

According to an embodiment, the central portion may include a core portion and a ring portion, wherein the ring portion laterally separates the first doped region and the core portion.

The ring portion may surround the core portion completely. The ring portion may include an insulator structure. Alternatively or in addition, the ring portion may include a doped semiconductor portion (doped ring portion). The first doped region and the doped ring portion may form the auxiliary junction. The shape of the core portion in the plane of the first surface may be an area-connected planar shape with one external boundary and no interior boundaries (holes), e.g. a circle, a rectangle with rounded corners, or a stadium.

The core portion may include at least one more concentric sub-portions, e.g., one, two or more concentric circular rings or stadium-shaped rings, wherein the sub-portions are separated from each other by further ring portions, wherein further the further ring portions may include further insulator ring portions and/or further doped ring portions. As the number of intermediate ring portions increases, the sub-portions of the core portion can be increasingly decoupled from the first doped region.

The shape of the ring portion in the plane of the first surface may be a circular ring, a rectangular frame with rounded corner sections, or a combination of a rectangular frame with two symmetric semicircular rings on opposite sides of the rectangular frame. If a doped ring portion has the same conductivity type as the first doped region, a maximum dopant concentration in the doped ring portion can be less than 10%, less than 1% or even less than 0.1% of an average dopant concentration in the first doped region.

Since the ring portion electrically separates the first doped region and the core portion at least to a certain degree, the ring portion allows more degrees of freedom in the design of the core portion.

According to an embodiment, the doped ring portion may have the second conductivity type.

The doped ring portion of the second conductivity type electrically separates the core portion from the first doped region to a high degree so that even a conducting core portion does not or only to a low degree contribute to the effective capacitance of the first doped region.

According to an embodiment, the core portion may include a floating island region of the first conductivity type.

The floating island region and the doped ring portion may form a third pn junction. In the plane of the first surface, the floating island region may fill the area within the doped ring portion completely. The floating island region is electrically separated from the first doped region and the second doped region and may be separated from other conductive structures inside and outside the semiconductor layer.

Forming the first doped region as a ring instead of an area without interior boundaries, adds curvature in the vertical dimension. The additional curvature may lower the possible breakdown voltage. The floating island region improves the electric field distribution in the central portion and may at least partly compensate the effect of the added curvature. When the electric field in the semiconductor layer changes fast, the floating island region reacts only slowly and has no or only a small effect on the effective capacitance.

According to an embodiment, a maximum vertical extension v0 of the core portion may be greater than a maximum vertical extension v1 of the inner doped region.

A greater vertical extension (vertical length) v0 of the core portion, e.g., the floating island region, improves the electric field distribution in the semiconductor layer and contributes to the reduction of the electric field along the inner doped region.

According to an embodiment, the maximum vertical extension v0 of the core portion is at least 150% of the maximum vertical extension v1 of the inner doped region.

In accordance with another embodiment, a half bridge circuit; may include a half bridge that includes aa high side switch and a low side switch, and gate driver circuit. The gate driver circuit may include a high side part configured to drive the high side switch and a low side part configured to drive the low side switch. The gate driver circuit may include a semiconductor device as described above, wherein the high-voltage semiconductor element of the semiconductor device is a level-shifter transistor configured to pass an electric signal from the high side part to the low side part or from the low side part to the high side part.

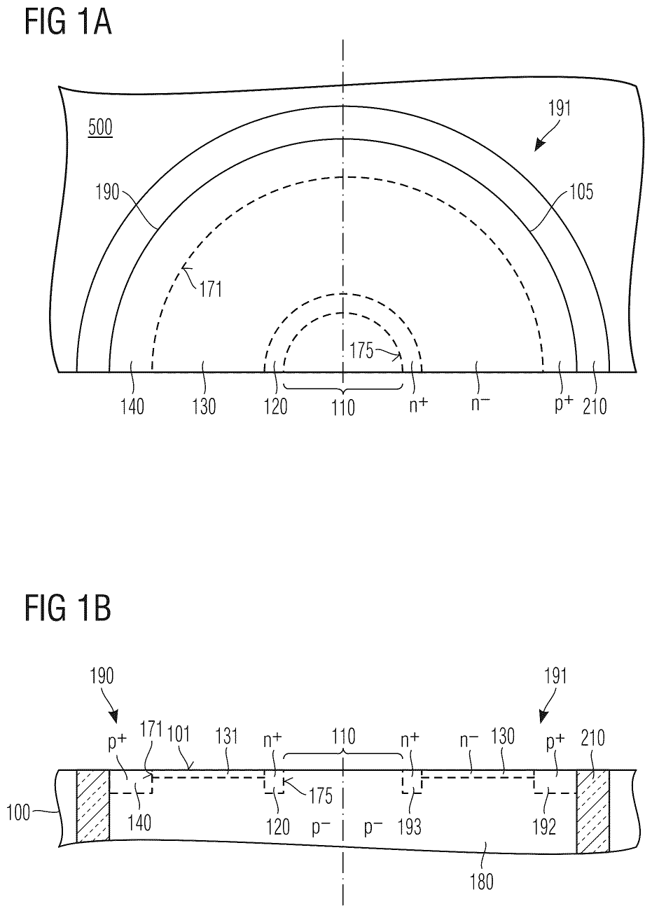

FIG. 1A and FIG. 1B show a portion of a semiconductor device 500 with a high-voltage semiconductor element 190. The high-voltage semiconductor element 190 is configured as lateral power semiconductor diode 191 with a nominal breakdown voltage higher than 100V, e.g., at least 600V or at least 1.6 kV.

Semiconducting regions of the semiconductor diode 191 are formed in a semiconductor layer 100 with a planar first surface 101 at a front side of the semiconductor device 500. The first surface 101 extends in a horizontal plane. A normal to the first surface 101 defines a vertical direction. The semiconductor layer 100 has a weak p-type background doping.

An n conductive first doped region 120 extends from the first surface 101 into the semiconductor layer 100. The first doped region 120 is configured as diode cathode region 193 and laterally surrounds a central portion 110 of the semiconductor diode 191. The central portion 110 is formed from a portion of the semiconductor layer 100 having the background doping. The diode cathode region 193 and the central portion 110 form an auxiliary junction 175, which is a pn junction in the illustrated example.

At a lateral distance from the first doped region 120, a p conductive second doped region 140 extends from the first surface 101 into the semiconductor layer 100 and laterally surrounds the first doped region 120 at a distance from the first doped region 120. The second doped region 140 is configured as diode anode region 192 of the semiconductor diode 191.

Between the first doped region 120 and the second doped region 140, a drift region 130 with a thin, n conductive drift zone 131 is formed in the semiconductor layer 100 along the first surface 101. In the lateral directions, the doped drift zone 131 extends from the first doped region 120 to the second doped region 140. The drift zone 131 and the first doped region 120 form a unipolar junction. The drift zone 131 and the second doped region 140 form a first pn junction 171.

The drift zone 131 may be spaced from the first surface 101. In the illustrated example, the drift zone 131 is in direct contact with the first surface 101.

A base portion 180 of the semiconductor layer 100 below the first doped region 120, the drift zone 131 and the second doped region 140 has a uniform p-type background doping. The drift zone 131 and the base portion 180 form a horizontal pn junction. The drift zone 131 is a lateral drain extension configured for a RESURF concept, wherein with increasing blocking voltage, a space charge region expanding from the horizontal pn junction completely depletes the drift zone 131 before a breakdown occurs between the first doped region 120 and the second doped region 140

An insulator structure 210 extends from the first surface 101 into the semiconductor layer 100. The insulator structure 210 laterally surrounds an element portion 105 of the semiconductor layer 100. The element portion 105 includes the central portion 110, the first doped region 120, the drift zone 131, the second doped region 140 and the base portion 180.

In the horizontal plane of the first surface 101, the central portion 110 may be a circle. The first doped region 120, the drift zone 131, the second doped region 140 and the insulator structure 210 may form rings, each of uniform width. The central portion 110, the first doped region 120, the drift zone 131, the second doped region 140 and the insulator structure 210 may be concentric circular rings.

Alternatively, the central portion 110 may form a stadium in the horizontal plane of the first surface 101. The first doped region 120, the drift zone 131, the second doped region 140 and the insulator structure 210 may form frames of different size around the central portion 110, wherein each frame has a uniform width.

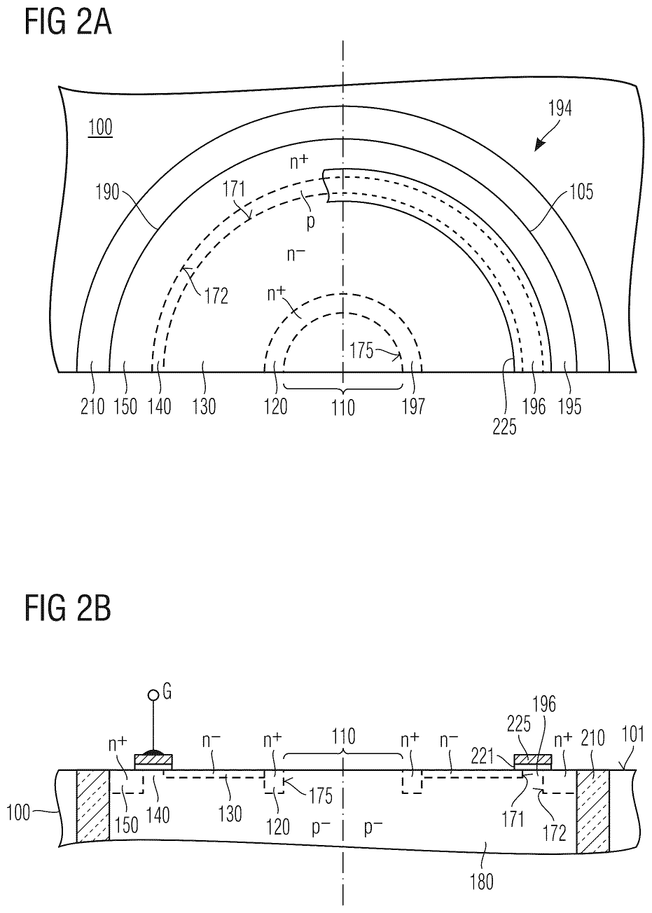

FIG. 2A and FIG. 2B show a semiconductor device 500 with a high-voltage semiconductor element 190 configured as n channel LDMOS field effect transistor 194 with a nominal breakdown voltage higher than 100V, e.g., at least 600V or at least 1.6 kV.

Semiconducting regions of the LDMOS field effect transistor 194 are formed in a semiconductor layer 100 with a planar first surface 101 at a front side of the semiconductor device 500.

An n conductive first doped region 120 extending from the first surface 101 into the semiconductor layer 100 is configured as transistor drain region 197 that laterally surrounds a central portion 110. The central portion 110 is formed from a portion of the semiconductor layer 100 having the background doping. The transistor drain region 197 and the central portion 110 form an auxiliary junction 175, which is a pn junction in the illustrated example.

At a lateral distance from the transistor drain region 197 (first doped region 120), a p conductive second doped region 140 extending from the first surface 101 into the semiconductor layer 100 laterally surrounds the transistor drain region 197 at a distance from the transistor drain region 197. The second doped region 140 is configured as transistor body region 196 of the LDMOS field effect transistor 194.

A gate conductor 225 based on a conductive material is formed on the first surface 101. A metal gate electrode G is connected to the gate conductor 225. A gate dielectric 221 based on an insulating material separates the gate conductor 225 and the transistor body region 196. An electric potential applied to the gate conductor 225 controls a lateral inversion channel through the transistor body region 196.

An n conductive third doped region 150 extends from the first surface 101 into the semiconductor layer 100 and laterally surrounds the transistor body region 196. The third doped region 150 is configured as transistor source region 195 of the lateral LDMOS field effect transistor 194.

Between the first doped region 120 and the second doped region 140, a drift region 130 includes a thin, n conductive doped drift zone 131 formed in the semiconductor layer 100 along the first surface 101. In the lateral directions, the doped drift zone 131 extends from the first doped region 120 to the second doped region 140. The drift zone 131 and the transistor drain region 197 (first doped region 120) form a unipolar junction. The drift zone 131 and the transistor body region 196 (second doped region 140) form a first pn junction 171. The transistor body region 196 and the transistor source region 195 (third doped region 150) form a second pn junction 172.

The drift zone 131 may be spaced from the first surface 101. In the illustrated example, the drift zone 131 is in direct contact with the first surface 101.

A base portion 180 of the semiconductor layer 100 below the first doped region 120, the drift zone 131, the second doped region 140, and the third doped region 150 has a uniform background doping of the p-type. The drift zone 131 and the base portion 180 form a horizontal pn junction. The drift zone 131 is configured for a RESURF concept.

An insulator structure 210 extends from the first surface 101 into the semiconductor layer 100. The insulator structure 210 laterally surrounds an element portion 105 of the semiconductor layer 100. The element portion 105 includes the central portion 110, the first doped region 120, the drift region 130 with the drift zone 131, the second doped region 140, the third doped region 150 and the base portion 180.

In the horizontal plane of the first surface 101, the central portion 110 may be a circle. The first doped region 120, the drift zone 131, the second doped region 140, the third doped region 150 and the insulator structure 210 may form rings, each of uniform width. The central portion 110, the first doped region 120, the drift zone 131, the second doped region 140, the third doped region 150 and the insulator structure 210 may be concentric circular rings.

Alternatively, the central portion 110 may form a stadium in the horizontal plane of the first surface 101. The first doped region 120, the drift zone 131, the second doped region 140, the third doped region and the insulator structure 210 may form frames of different size around the central portion 110, each of the frames having a uniform width.

Reducing the transistor drain region 197 (first doped region 120) to a donut-like shape reduces the area of an effective capacitance between the transistor drain region 197 and the transistor source region 195, the drain-to-source capacitance CDS and, consequently, the output capacitance Coss of the LDMOS field effect transistor 194.

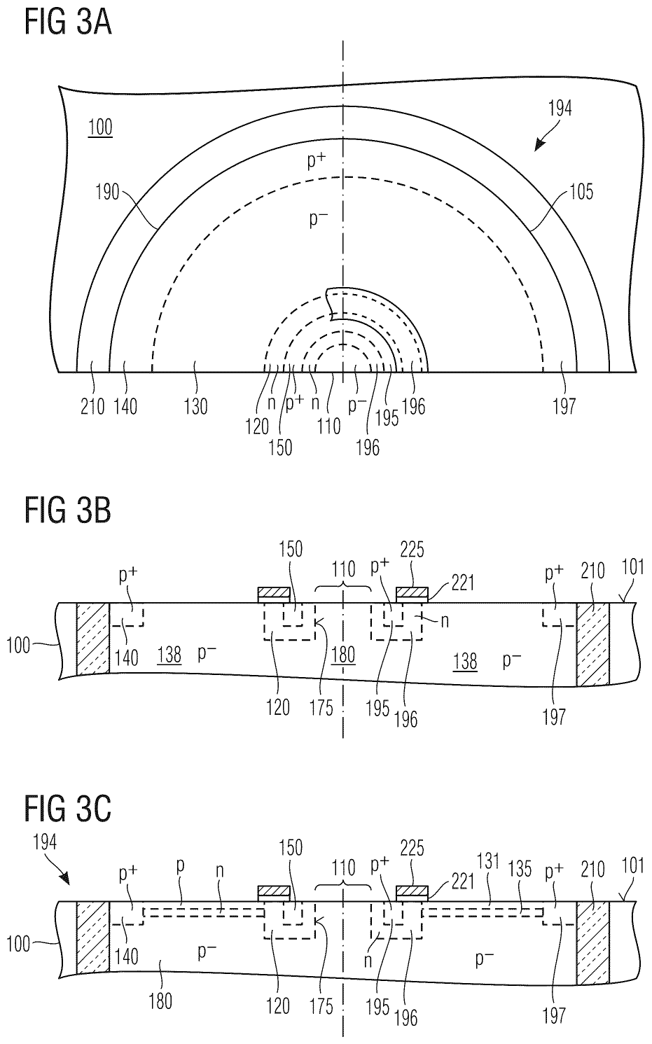

In FIG. 3A and FIG. 3B the illustrated semiconductor device 500 includes a high-voltage semiconductor element 190 configured as p channel LDMOS field effect transistor 194 with a nominal breakdown voltage higher than 100V, for example at least 600V or at least 1.6 kV.

An n conductive first doped region 120 extending from the first surface 101 into a semiconductor layer 100 is configured as transistor body region 196 that laterally surrounds a central portion 110 of the LDMOS field effect transistor 194. The central portion 110 is formed from a portion of the semiconductor layer 100 having the background doping. The transistor body region 196 and the central portion 110 form an auxiliary junction 175, which is a pn junction in the illustrated example.

A gate conductor 225 based on a conductive material is formed on the first surface 101. A gate dielectric 221 based on an insulating material separates the gate conductor 225 and the transistor body region 196. An electric potential applied to the gate conductor 225 controls a lateral inversion channel through the transistor body region 196.

At a lateral distance from the transistor body region 196 (first doped region 120), a p conductive second doped region 140 extending from the first surface 101 into the semiconductor layer 100 laterally surrounds the transistor body region 196 at a distance from the transistor body region 196. The second doped region 140 is configured as transistor drain region 197 of the LDMOS field effect transistor 194.

A p conductive third doped region 150 extends from the first surface 101 into the transistor body region 196 (first doped region 120) and laterally surrounds the central portion 110. The third doped region 150 is configured as transistor drain region 197 of the lateral LDMOS field effect transistor 194.

A base portion 180 of the semiconductor layer 100 below the first doped region 120 and the second doped region 140 has a uniform background doping of the p-type. A drift portion 138 of the base portion 180 along the first surface 101 may be effective as the drift region 130.

An insulator structure 210 extending from the first surface 101 into the semiconductor layer 100 surrounds an element portion 105 of the semiconductor layer 100, wherein the element portion 105 includes the central portion 110, the first doped region 120, the drift region 130, the second doped region 140, the third doped region 150 and the base portion 180.

For the shapes of the different doped regions in the horizontal plane, reference is made to the detailed description of FIG. 2A and FIG. 2B.

The LDMOS field effect transistor 194 illustrated in FIGS. 3A and 3B benefits from the donut-shaped transistor body region 196 for similar reasons as the LDMOS field effect transistor 194 illustrated in FIGS. 2A and 2B.

FIG. 3C shows an LDMOS field effect transistor 194 with a p doped drift zone 131 formed along the first surface 101 of the semiconductor layer 100 and an n doped RESURF layer 135 formed between the p doped drift zone 131 and the weakly p-doped base portion 180. The RESURF layer 135 extends along the complete radial extension of the drift zone 131 between the first doped region 120 and the second doped region 140.

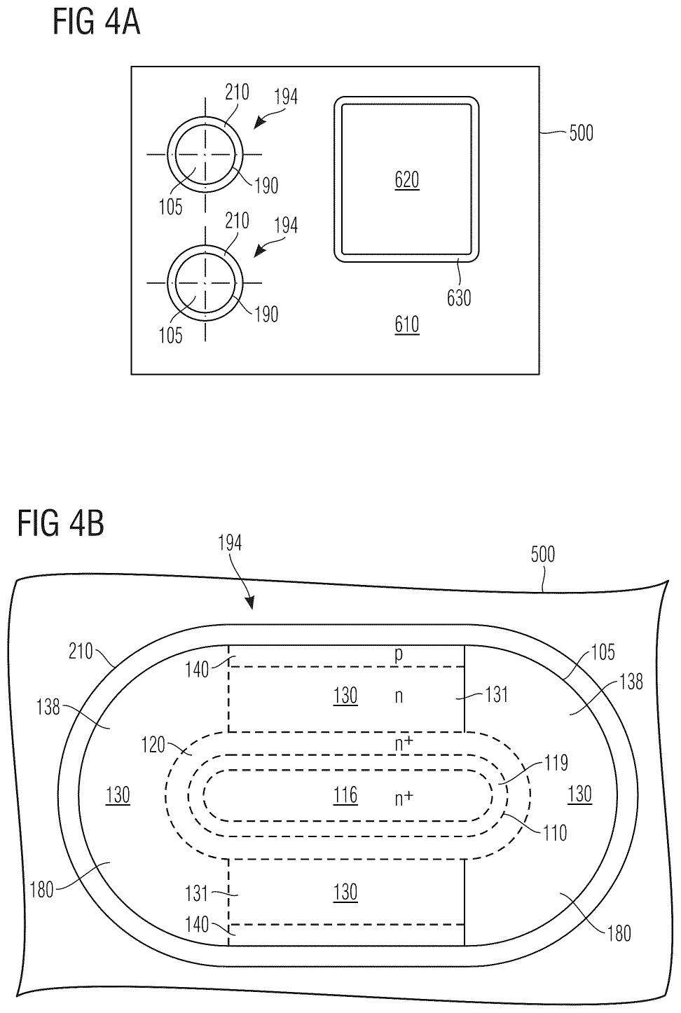

FIG. 4A shows a semiconductor device 500 that includes first CMOS circuits in a low side part 610 and second CMOS circuits in a high side part 620. A domain insulator structure 630 with high breakdown voltage capability forms a closed frame around the high side part 620.

Spatially separated from the high side part 620, the semiconductor device 500 includes two high-voltage semiconductor elements 190 configured as LDMOS field effect transistors 194. Ring-shaped insulator structures 210 electrically separate element portions 105 of the semiconductor elements 190 within the insulator structures 210 from the low side part 610.

In FIG. 4B, a horizontal shape of the central portion 110 includes a rectangular portion and two semicircular portions on opposite sides of the rectangular portion (stadium-shape). A core portion 116 of the central portion 110 has a stadium-shape. A ring portion 119 of the central portion 110 surrounds the core portion 116 at uniform width. A first doped region 120 surrounds the central portion 110 at uniform width. An insulator structure 210 forms a closed frame with two half rings and two straight sections connecting the half rings. The insulator structure 210 surrounds an element portion 105 of a semiconductor layer. A drift region 130 is formed between the first doped region 120 and the insulator structure 210. The drift region 130 includes two doped drift zones 131 formed along the long sides of the first doped region 120. The element region 105 further includes two second doped regions 140 laterally separated from the first doped region 120 by the doped drift zones 131. Each doped drift zone 131 laterally extends from the first doped region 120 to one of the second doped regions 140. Two drift portions 138 of the base portion 180 form two half ring shaped portions of the drift region 130 along the rounded section of the first doped region 120.

The first and second doped regions 120, 140 can be the cathode and anode regions of a high voltage semiconductor diode, or the drain region and the body region of a drain-inside LDMOS field effect transistor, the LDMOS S field effect transistor further including a heavily n doped transistor source region embedded in the second doped region 140 (body region).

FIG. 5 to FIG. 10 illustrate differently formed central portions 110 for various types of LDMOS field effect transistors 194.

FIG. 5 refers to an LDMOS field effect transistors 194 in a drain-inside configuration. A ring-shaped first doped region 120 extends from a first surface 101 into a semiconductor layer 100. The first doped region 120 is configured as transistor drain region 197 laterally surrounding the central portion 110. The central portion 110 is homogenously doped and has the weak p-type background doping of the base portion 180. A weakly doped n-type drift zone 131 configured for a RESURF concept is formed in the semiconductor layer 100 along the first surface 101 and surrounds the transistor drain region 197.

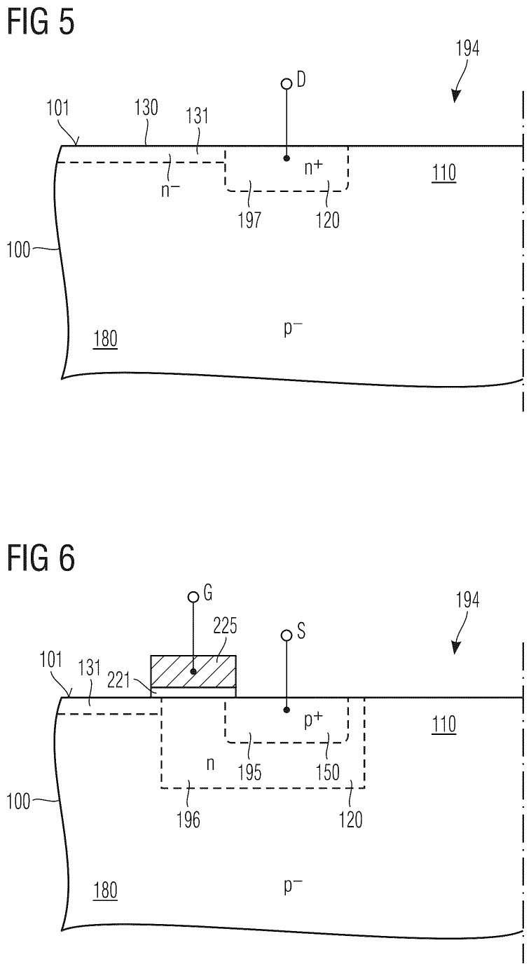

FIG. 6 refers to an LDMOS field effect transistors 194 in a source-inside configuration with a ring-shaped first doped region 120 configured as transistor body region 196 laterally surrounding the central portion 110. A gate dielectric 221 formed on the first surface 101 separates a gate conductor 225 and the transistor body region 196. A heavily doped p-type third doped region 150 extends from the first surface 101 into the transistor body region 196. The central portion 110 is homogenously doped and has the weak p-type background doping of the base portion 180.

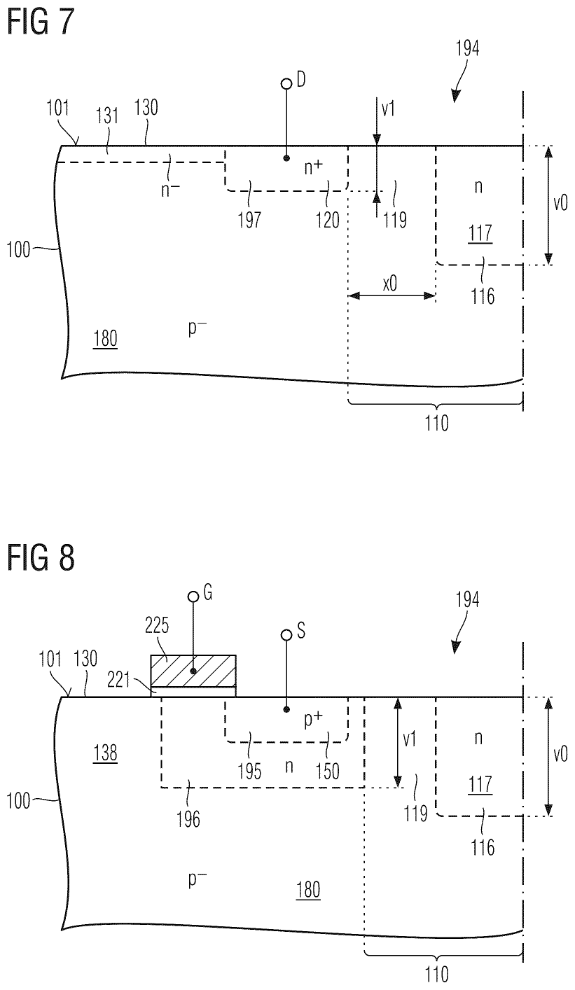

The central portion 110 of an LDMOS field effect transistor 194 in a drain-inside configuration illustrated in FIG. 7 includes a core portion 116 and a concentric doped ring portion 119. The doped ring portion 119 laterally surrounds the core portion 116 and laterally separates the core portion 116 from the first doped region 120 (transistor drain region 197). The core portion 116 has the conductivity type of the first doped region 120. The doped ring portion 119 is formed from a portion of the homogenously doped background portion 180. A maximum vertical extension v0 of the core portion is at least 150%, or at least 200% of a maximum vertical extension v1 of the first doped region 120. A lateral width x0 of the doped ring portion 116 is in a range from 2 μm to 15 μm. A diameter of the core portion 119 is in a range from 5 μm to 100 μm.

The core portion 116 is without low-resistive ohmic connection to any of the electrodes of the LDMOS field effect transistor 194 and forms a floating island region 117. The floating island region 117 compensates to some degree the effect of the increased curvature of a ring-shaped first doped region on the electric field distribution comparted to a circular first doped region of the same diameter and same vertical extension.

FIG. 8 combines the central portion 110 with core portion 116 and doped ring portion 119 of FIG. 7 with the source-inside LDMOS field effect transistor 194 of FIG. 6. A drift portion 138 of the base portion 180 forms at least a part of the drift region 130.

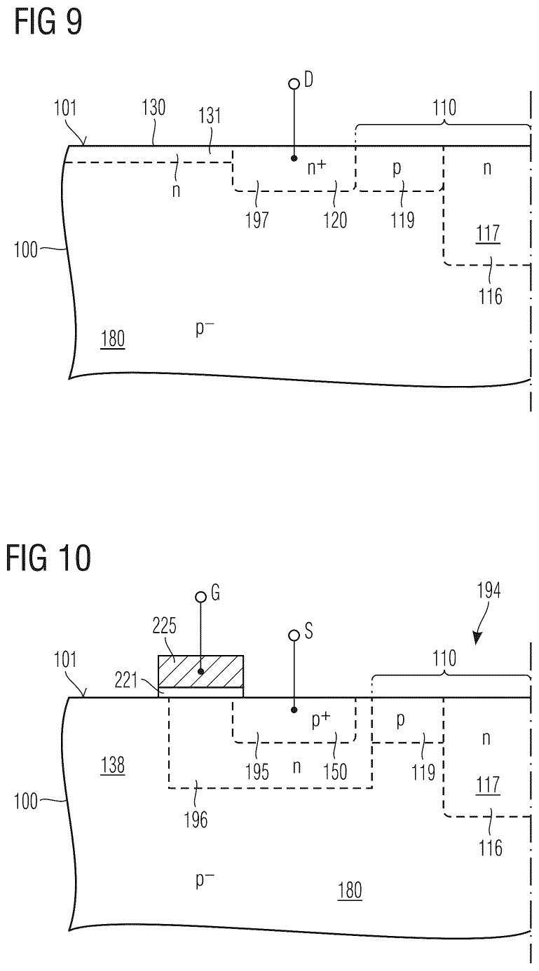

FIG. 9 combines the central portion 110 with floating island region 117 for a drain-inside LDMOS field effect transistor 194 as illustrated in FIG. 7 with a doped ring portion 119 having a higher dopant concentration than the uniform background doping in the base portion 180. The doped ring portion 119 forms a well containing implanted acceptor atoms and extends between the first doped region 120 and the floating island region 117 from the first surface 101 into the semiconductor layer 100. A maximum dopant concentration in the doped ring portion 119 is at least 2× or at least 1000× an average dopant concentration in the base portion 180.

FIG. 10 combines the central portion 110 with core portion 116 and heavily doped ring portion 119 of FIG. 9 with the source-inside LDMOS field effect transistor 194 of FIG. 6.

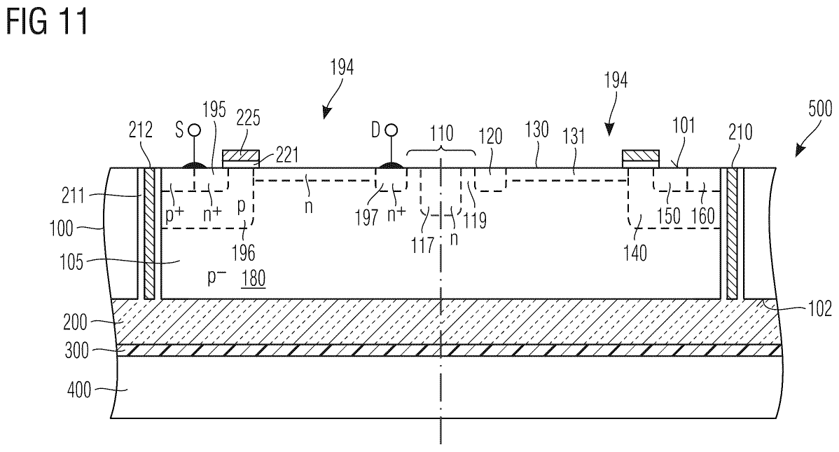

The semiconductor device 500 of FIG. 11 includes a drain-inside LDMOS field effect transistor 194 based on the LDMOS field effect transistor 194 of FIG. 2A and FIG. 2B. The element portion 105 further includes a heavily doped p-type base contact region 160 between the second doped region 140 (transmitter body region 196) and the insulator structure 210 and in direct contact with the second doped region 140 (transmitter body region 196). The base contact region 160 may laterally surround the third doped region 150 (transistor source region 195). The base contact region 160 and the transistor source region 195 form low-resistive ohmic contacts with a metal source electrode S. The transistor drain region 197 forms a low-resistive ohmic contact with a metal drain electrode D.

Insulator layer 200 is formed along a second surface 102 of the semiconductor layer 100 opposite to the first surface 101. The semiconductor layer 100 and the insulator layer 200 are in an SOI (silicon-on-insulator) configuration. The insulator layer 200 may include or consist of a semiconductor oxide, e.g., silicon oxide. A thickness of the insulator layer 200 may be in a range from 1 μm to 20 μm, preferably in a range from 4 μm to 15 μm.

The insulator structure 210 extends from the first surface 101 down to the insulator layer 200, so that the insulator structure 210 and the insulator layer 200 completely embed the element portion 105, which includes all doped regions of the LDMOS field effect transistor 194, on all sides. The insulator structure 210 includes a conductive fill 212 and an insulating lining layer 211 that separates the conductive fill 212 from the material of the semiconductor layer 100.

An adhesive layer 300 mechanically connects a planar rear side of the insulator layer 200 with a planar reinforcing layer 400.

The adhesive layer 300 may consist of an adhesive resin or may include adhesive resin layers applied on opposite sides of a carrier tape. A thickness of the adhesive layer 300 may be in a range from 5 nm to 30 nm.

The reinforcing layer 400 may consist of or include a homogenously doped or intrinsic semiconductor layer. A thickness of the reinforcing layer 400 is selected such that a total thickness of the layer compound including the semiconductor layer 100, the insulator layer 200, the adhesive layer 300, and the reinforcing layer 400 is at least 150 μm, e.g., at least 200 μm.

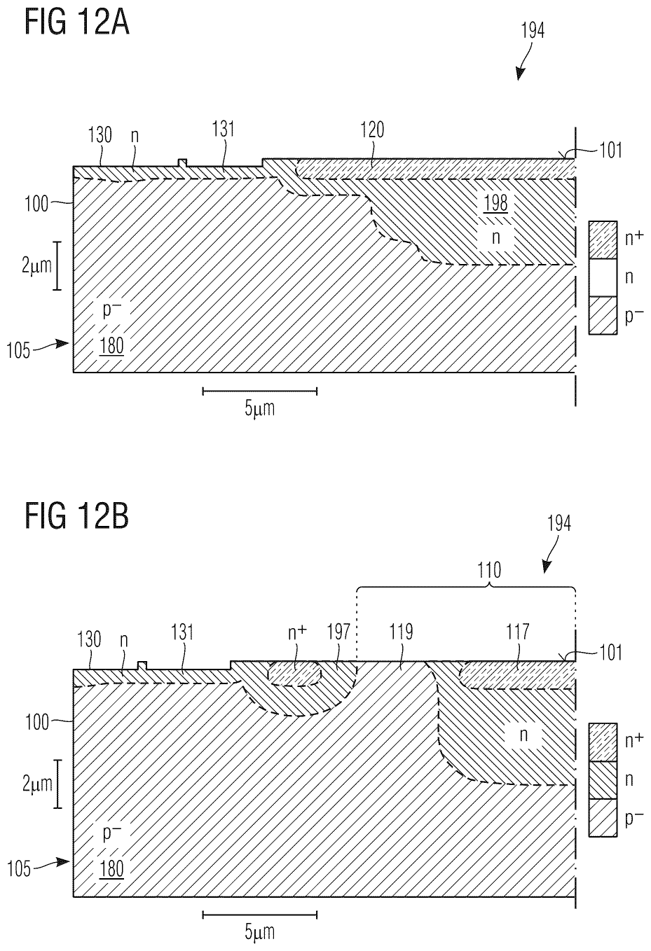

FIG. 12A shows equipotential lines in an element portion 105 of a drain-inside n-channel LDMOS field effect transistor 194 at a drain-to-source voltage of 300V according to a comparative example with a circular n-type transistor drain region 198 without opening.

FIG. 12B shows the equipotential lines in an element portion 105 of a drain-inside n-channel LDMOS field effect transistor 194 at the same drain-to-source voltage VDS according to an example with an annular n-type transistor drain region 197 surrounding a central portion 110, wherein the central portion 110 includes a p-type doped ring portion 119 and an n-type floating island region 117.

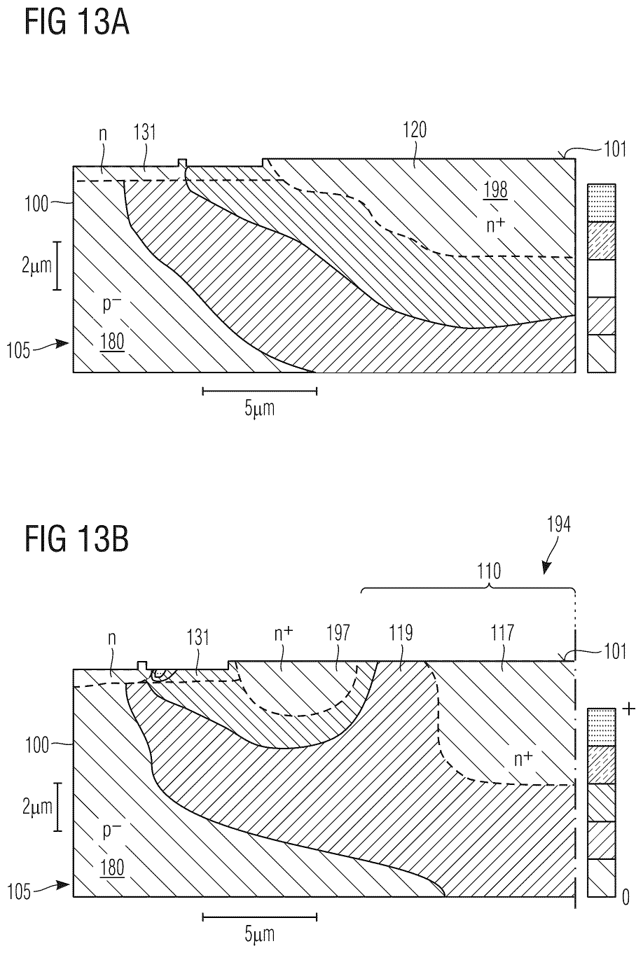

FIG. 13A shows the displacement current distribution in the element portion 105 of FIG. 12A and FIG. 13B shows the displacement current distribution in the element portion 105 of FIG. 12B at a drain-to-source voltage VDS of 2V. In the surrounding of the floating island region 117, the displacement current is significantly reduced indicating the lower contribution of the floating island region 117 to the drain-to-source capacitance CDS and the output capacitance COSS.

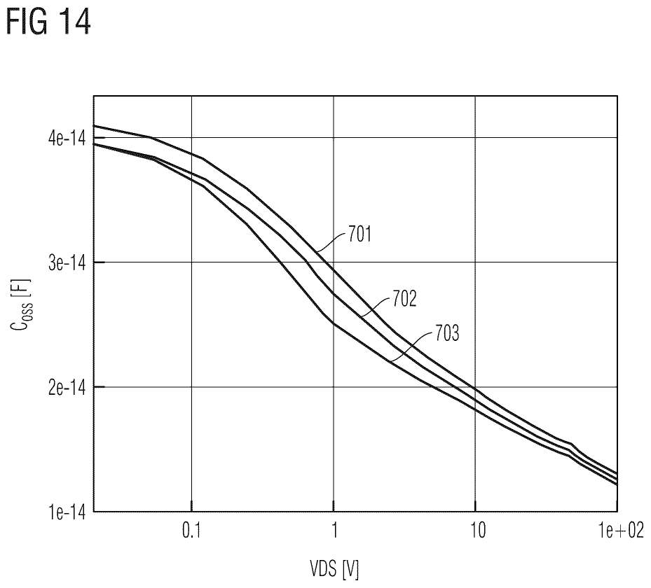

In FIG. 14, line 701 shows the output capacitance Coss of a drain-inside n-channel LDMOS field effect transistor as a function of the drain-to-source voltage VDS according to a comparative example with a circular n-type transistor drain region without opening. Lines 702, 703 show the output capacitance Coss of drain-inside n-channel LDMOS field effect transistors as function of the drain-to-source voltage VDS for examples with an annular n-type transistor drain region surrounding a central portion, wherein the central portion includes a p-type doped ring portion and an n-type floating island region. A ring-shaped transistor drain region in combination with a floating island region reduces the output capacitance for drain-to-source voltages VDS.

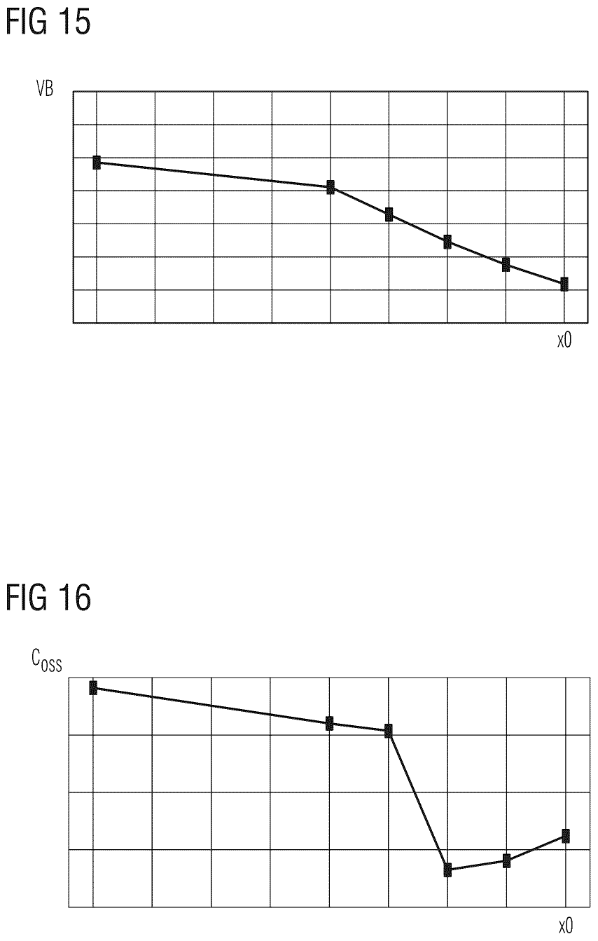

FIG. 15 shows the breakdown voltage VB of the LDMOS field effect transistor of FIG. 12B and FIG. 13B as a function of the width x0 of the doped ring portion 119 of the central portion 110, wherein the width x0 of the doped ring portion 119 corresponds to a distance (gap width) between the transistor drain region 197 and the floating island region 117 in FIG. 12B. The breakdown voltage VB decreases with increasing gap width x0, wherein the decrease is moderate for gap widths x0 up to 20 μm, or, up to 5 μm.

FIG. 16 shows the output capacitance Coss of the LDMOS field effect transistor of FIG. 12B and FIG. 13B as a function of the gap width x0. The output capacitance Coss has a minimum at a gap width x0 of about 6 μm.

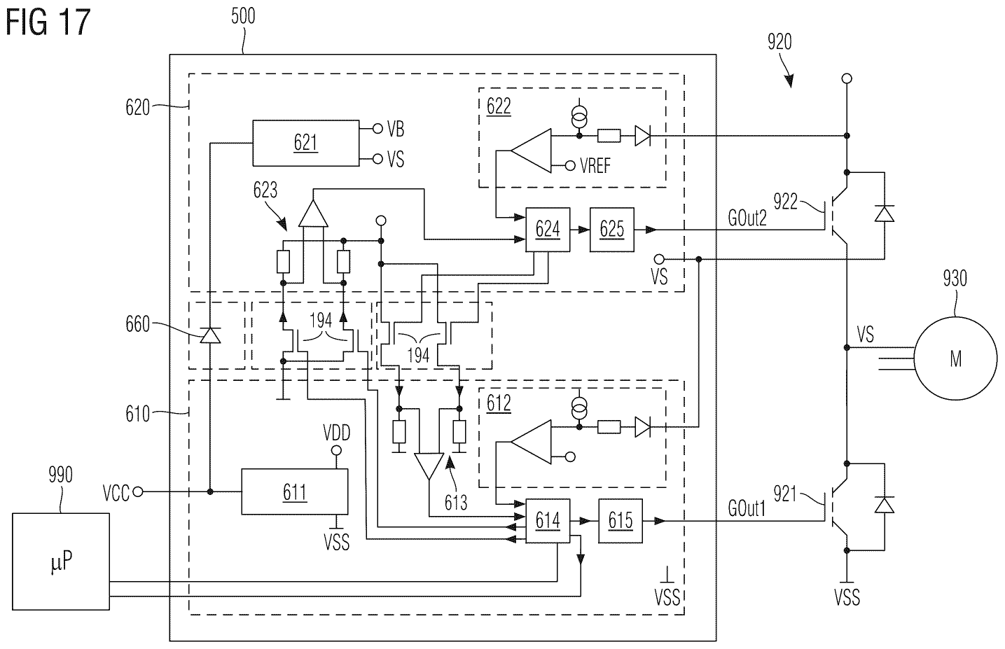

FIG. 17 shows a semiconductor device 500 configured as gate driver circuit. The gate driver circuit includes a high side part 620 configured to drive a gate of a high side switch 922 of a half bridge and a low side part 610 configured to drive a gate of a low side switch 921 of the half bridge. The semiconductor device 500 includes a high side power supply circuit 621 to obtain a positive power supply voltage VB for the high side part 620 (high side supply potential VB), wherein a bootstrap diode 660 charges a bootstrap capacitor from an external supply voltage VCC. The positive power supply voltage VB for the high side part 620 is referenced to a high side reference potential VS, which corresponds to the potential of the output node of a half bridge 920.

A high side desaturation detection circuit 622 is connected to the supply potential VA of the half bridge 920, detects a desaturation of the high side switch 922 of the half bridge 920, and outputs a high side desaturation signal indicating whether a desaturation condition exists. A high side receiver circuit 623 receives a differential gate control signal from two n-channel LDMOS field effect transistors 194 as described above and outputs a single-ended high side gate control signal. A logic circuit 624 in the high side part 620 receives the high side desaturation signal and the high side gate control signal. The logic circuit 624 in the high side part 620 outputs a second gate drive signal GOut2 in response to the high side gate control signal provided that the high side desaturation signal does not indicate a desaturation condition. A high side driver stage 625 may drive the second gate drive signal GOut2.

The logic circuit 624 in the high side part further outputs a differential high side data signal. Two p channel LDMOS field effect transistors 194 transmit the differential high side data signal from the high side part 620 to a low side receiver circuit 613 in the low side part 610.

The low side part 610 of the gate driver circuit includes a low side power supply circuit 611 to obtain a positive power supply voltage VDD for the low side part 610. The positive power supply voltage VDD for the low side part 610 is referenced to the first reference potential VSS.

A low side desaturation detection circuit 612 is connected to the output node of the half bridge 920, detects a desaturation of the low side switch 921, and outputs a low side desaturation signal indicating whether a desaturation condition exists. A low side receiver circuit 613 receives a differential low side data signal from the two p channel LDMOS field effect transistors 194 and outputs a single-ended low side data signal. A logic circuit 614 in the low side part 610 receives the low side data signal, the low side desaturation signal, and a low side gate control signal from an external source like a processor 990. The logic circuit 614 in the low side part 610 outputs a first gate drive signal GOut1 in response to the low side gate control signal provided that none of the low side desaturation signal and the low side data signal indicates a desaturation condition. A low side driver stage 615 drives the first gate drive signal GOut1.

The logic circuit 614 in the low side part 610 further outputs a differential gate control signal. The two n channel LDMOS field effect transistors 194 transmit the differential gate control signal from the low side part 610 to the high side part 620. An inductive load 930 is electrically connected between the switching nodes of two half bridges 920.

The LDMOS field effect transistors 194 can have any of the configurations of the present embodiments, improve the signal transfer between the low side part 610 and the high side part 620 and improve the performance of the half bridge 920 by allowing higher switching frequencies.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device comprising a high-voltage semiconductor element, the high-voltage semiconductor element comprising:
a semiconductor layer having a first surface at a front side of the semiconductor layer;
a first doped region of a first conductivity type at least partially laterally surrounding a central portion, the central portion and the first doped region forming an auxiliary junction;
a second doped region of a second conductivity type at least partially laterally surrounding the first doped region; and
a drift region of the first or second conductivity type extending from the first doped region to the second doped region and forming a first pn junction with the first doped region or the second doped region.

2. The semiconductor device of claim 1, wherein the auxiliary junction comprises a unipolar junction or a pn junction.

3. The semiconductor device of claim 1, wherein the drift region comprises a doped drift zone of the first or second conductivity type extending between the first surface of the semiconductor layer and a lightly doped base portion of the semiconductor layer from the first doped region to the second doped region, and wherein the doped drift zone forms the first pn junction with the first doped region or the second doped region.

4. The semiconductor device of claim 3, wherein the doped drift zone is configured to be fully depleted at a voltage lower than 30% of a breakdown voltage of the semiconductor device.

5. The semiconductor device of claim 4, further comprising:
an insulator layer formed along a second surface of the semiconductor layer, wherein the second surface is opposite to the first surface.

6. The semiconductor device of claim 4, further comprising:
an insulator structure extending from the first surface of the semiconductor layer to the insulator layer, wherein the insulator structure laterally surrounds an element portion of the semiconductor layer, the element portion comprising a plurality of doped regions of the semiconductor element.

7. The semiconductor device of claim 1, wherein the high-voltage semiconductor element comprises a semiconductor diode with a first one of the first doped region and the second doped region forming a diode anode region of the semiconductor diode, and with a second one of the first doped region and the second doped region forming a diode cathode region of the semiconductor diode.

8. The semiconductor device of claim 1, further comprising:
a third doped region of the conductivity type of the first doped region and laterally separated from the drift region by a transistor body region of a complementary conductivity type, wherein the transistor body region comprises at least a portion of the second doped region or the first doped region.

9. The semiconductor device of claim 8, wherein the third doped region is embedded in the transistor body region, and wherein the second doped region and the third doped region form a second pn junction.

10. The semiconductor device of claim 8, wherein a portion of the first doped region laterally embeds the third doped region, and wherein the first doped region and the third doped region form a second pn junction.

11. The semiconductor device of claim 8, wherein at least three of the first doped region, the doped drift region, the second doped region, and the third doped region form wells extending from the first surface at the front side of the semiconductor layer into the semiconductor layer.

12. The semiconductor device of claim 1, wherein the central portion has the second conductivity type or the first conductivity type with a maximum dopant concentration of at most 10% of an average dopant concentration in the first doped region.

13. The semiconductor device of claim 1, wherein the central portion comprises a core portion and a ring portion, and wherein the ring portion laterally separates the first doped region and the core portion.

14. The semiconductor device of claim 13, wherein the ring portion has the second conductivity type.

15. The semiconductor device of claim 13, wherein the core portion comprises a floating island region of the first conductivity type.

16. The semiconductor device of claim 13, wherein a maximum vertical extension of the core portion is greater than a maximum vertical extension of the inner doped region.

17. The semiconductor device of claim 16, wherein the maximum vertical extension of the core portion is at least 150% of the maximum vertical extension of the inner doped region.

18. A half bridge circuit; comprising:
a half bridge comprising a high side switch and a low side switch; and
a gate driver circuit comprising a high side part configured to drive the high side switch and a low side part configured to drive the low side switch,
wherein the gate driver circuit comprises the semiconductor device of claim 1,
wherein the high-voltage semiconductor element of the semiconductor device is a level-shifter transistor configured to pass an electric signal from the high side part to the low side part and/or from the low side part to the high side part.
